(19) United States
(12) Patent Application Publication
(10) Pub. No.: US 2025/0015201 A1
(43) Pub. Date: Jan. 9, 2025

(54) JUNCTION BARRIER SCHOTTKY DIODE

(71) Applicant: TDK CORPORATION, Tokyo (JP)

(72) Inventors: Jun ARIMA, Tokyo (JP); Minoru FUJITA, Tokyo (JP); Katsumi KAWASAKI, Tokyo (JP); Jun HIRABAYASHI, Tokyo (JP)

(21) Appl. No.: 18/891,085

(22) Filed: Sep. 20, 2024

Related U.S. Application Data
(63) Continuation of application No. PCT/JP2023/000365, filed on Jan. 11, 2023.

(30) Foreign Application Priority Data
Mar. 23, 2022 (JP) 2022-047238

(51) Int. Cl. H01L 29/872

(52) U.S. Cl. CPC H01L 29/872

(57) ABSTRACT

Disclosed herein is a junction barrier Schottky diode that includes a semiconductor substrate, a drift layer provided on the semiconductor substrate, an anode electrode contacting the drift layer, a cathode electrode contacting the semiconductor substrate, and a p-type semiconductor layer contacting both the anode electrode and the drift layer. The p-type semiconductor layer includes a first p-type semiconductor layer contacting the anode electrode and a second p-type semiconductor layer contacting the drift layer. The second p-type semiconductor layer is lower in valence band upper end level than the first p-type semiconductor layer.

### BACKGROUND OF THE ART

The present disclosure relates to a junction barrier Schottky diode.

A Schottky barrier diode is a rectifying element utilizing a Schottky barrier generated due to bonding between metal and a semiconductor and is lower in forward voltage and higher in switching speed than a normal diode having a PN junction. Thus, the Schottky barrier diode is sometimes utilized as a switching element for a power device.

When the Schottky barrier diode is utilized as a switching element for a power device, it is necessary to ensure a sufficient backward withstand voltage, so that silicon carbide (SiC), gallium nitride (GaN), or gallium oxide (Ga₂O₃) having a larger band gap is sometimes used in place of silicon (Si). Among them, gallium oxide has a very large band gap (4.8 eV to 4.9 eV) and a large breakdown field of about 8 MV/cm, so that a Schottky barrier diode using gallium oxide is very promising as the switching element for a power device. An example of the Schottky barrier diode using gallium oxide is described in JP 2019-036593 A.

JP 2019-036593 A discloses a junction barrier Schottky diode having a structure in which a plurality of trenches provided in a gallium oxide layer are filled with a p-type semiconductor material. By thus providing a plurality of trenches in the gallium oxide layer and filling the plurality of trenches with a p-type semiconductor material, a mesa region positioned between the trenches becomes a depletion layer upon application of a backward voltage, so that a channel region of a drift layer is pinched off. Thus, a leak current upon application of the backward voltage can be significantly reduced.

However, in the junction barrier Schottky diode described in JP 2019-036593 A, when a material whose valence band upper end level is close to the Fermi level is selected as the material of a p-type semiconductor layer, a difference between the valence band upper end level of the selected material and that of a drift layer becomes large to require large energy for hole injection into the drift layer, thus deteriorating surge resistance. Conversely, when a material whose valence band upper end level is close to the valence band upper end level of the drift layer is selected as the material of a p-type semiconductor layer, a difference between the valence band upper end level of the selected material and the Fermi level becomes large to increase contact resistance between an anode electrode and the p-type semiconductor layer. This also deteriorates surge resistance.

### SUMMARY

It is desirable to increase surge resistance of a junction barrier Schottky diode.

A junction barrier Schottky diode according to the present disclosure includes: a semiconductor substrate; a drift layer provided on the semiconductor substrate; an anode electrode contacting the drift layer; a cathode electrode contacting the semiconductor substrate; and a p-type semiconductor layer contacting both the anode electrode and the drift layer. The p-type semiconductor layer includes a first p-type semiconductor layer contacting the anode electrode and a second p-type semiconductor layer contacting the drift layer, and the second p-type semiconductor layer is lower in valence band upper end level than the first p-type semiconductor layer.

### BRIEF DESCRIPTION OF THE DRAWINGS

FIG. 1A is a schematic plan view illustrating the configuration of a junction barrier Schottky diode 1 according to a first embodiment of the present disclosure.

FIG. 1B is a schematic cross-sectional view taken along the line A-A in FIG. 1A.

FIGS. 2A and 2B are energy band diagrams of the junction barrier Schottky diode 1, where FIG. 2A illustrates an energy band along the first current path P1, and FIG. 2B illustrates an energy band along the second current path P2.

FIG. 3 is a graph illustrating the relation between a forward voltage VF and a forward current IF.

FIG. 4 is a schematic plan view illustrating the configuration of a junction barrier Schottky diode according to a first modification.

FIG. 5 is a schematic plan view illustrating the configuration of a junction barrier Schottky diode according to a second modification.

FIG. 6 is a schematic plan view illustrating the configuration of a junction barrier Schottky diode according to a third modification.

FIG. 7 is a schematic plan view illustrating the configuration of a junction barrier Schottky diode according to a fourth modification.

FIG. 8A is a schematic plan view illustrating the configuration of a junction barrier Schottky diode according to a fifth modification.

FIG. 8B is a schematic cross-sectional view taken along the line A-A in FIG. 8A.

FIG. 9A is a schematic plan view illustrating the configuration of a junction barrier Schottky diode according to a sixth modification.

FIG. 9B is a schematic cross-sectional view taken along the line A-A in FIG. 9A.

FIG. 10A is a schematic plan view illustrating the configuration of a junction barrier Schottky diode according to a seventh modification.

FIG. 10B is a schematic cross-sectional view taken along the line A-A in FIG. 10A.

FIG. 11A is a schematic plan view illustrating the configuration of a junction barrier Schottky diode 2 according to a second embodiment of the present disclosure.

FIG. 11B is a schematic cross-sectional view taken along the line A-A in FIG. 11A.

FIG. 12 is a schematic plan cross-sectional illustrating the configuration of a junction barrier Schottky diode according to an eighth modification.

FIG. 13 is a schematic cross-sectional view illustrating the configuration of a junction barrier Schottky diode 3 according to a third embodiment of the present disclosure.

FIG. 14 is an energy band diagram of the junction barrier Schottky diode 3, which illustrates an energy band along the second current path P2.

FIG. 15 is an energy band diagram according to a first example in which the p-type semiconductor layer 60 has an n-layer structure.

FIG. 16 is an energy band diagram according to a second example in which the p-type semiconductor layer 60 has an n-layer structure.

### DETAILED DESCRIPTION OF THE EMBODIMENTS

Hereinafter, some embodiments of the present disclosure will be described in detail with reference to the accompanying drawings.

### First Embodiment

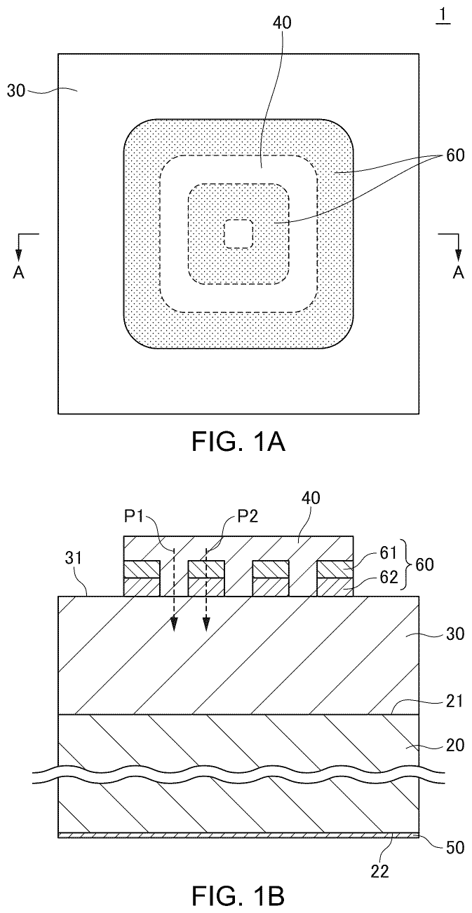

FIG. 1A is a schematic plan view illustrating the configuration of a junction barrier Schottky diode 1 according to a first embodiment of the present disclosure and FIG. 1B is a schematic cross-sectional view taken along the line A-A in FIG. 1A.

As illustrated in FIGS. 1A and 1B, the junction barrier Schottky diode 1 according to the first embodiment has a semiconductor substrate 20 and a drift layer 30, both of which are made of gallium oxide (β-Ga₂O₃). The semiconductor substrate 20 and drift layer 30 are each introduced with silicon (Si) or tin (Sn) as an n-type dopant. The concentration of the dopant is higher in the semiconductor substrate 20 than in the drift layer 30, whereby the semiconductor substrate 20 and the drift layer 30 function as an n⁺ layer and an n⁻ layer, respectively. The impurity concentration of the semiconductor substrate 20 is, for example, about 1×10¹⁸ cm⁻³, and the impurity concentration of the drift layer 30 is, for example, about 1×10¹⁶ cm⁻³.

The semiconductor substrate 20 is obtained by cutting a bulk crystal formed using a melt-growing method and has a thickness of about 250 μm. The planar size of the semiconductor substrate 20 is not particularly limited and is generally selected in accordance with the amount of current flowing in the element. For example, when the maximum amount of forward current is about 20A, the planar size may be set to about 2.4 mm×2.4 mm.

The semiconductor substrate 20 has an upper surface 21 positioned on the upper surface side in a mounted state and a back surface 22 positioned on the lower surface side in a mounted state. The drift layer 30 is formed on the entire upper surface 21. The drift layer 30 is a thin film obtained by epitaxially growing gallium oxide on the upper surface 21 of the semiconductor substrate 20 using a reactive sputtering method, a PLD method, an MBE method, an MOCVD method, or an HVPE method. The film thickness of the drift layer 30 is not particularly limited and is generally selected in accordance with the backward withstand voltage of the element. For example, in order to ensure a withstand voltage of about 600 V, the film thickness may be set to about 7 μm.

There are formed, on an upper surface 31 of the drift layer 30, an anode electrode 40 which is brought into Schottky contact with the drift layer 30 and a p-type semiconductor layer 60 which forms pn-junction with the drift layer 30. The anode electrode 40 is formed of metal such as platinum (Pt), palladium (Pd), gold (Au), nickel (Ni), molybdenum (Mo), or Copper (Cu). The anode electrode 40 may have a multilayer structure of different metal films, such as Pt/Au, Pt/Al, Pd/Au, Pd/Al, Pt/Ti/Au, or Pd/Ti/Au.

The p-type semiconductor layer 60 includes a first p-type semiconductor layer 61 and a second p-type semiconductor layer 62. The p-type semiconductor layer 60 has a double-ring shape in a plan view, and the second p-type semiconductor layer 62 and first p-type semiconductor layer 61 are stacked in this order on the flat upper surface 31 of the drift layer 30. As a result, the first p-type semiconductor layer 61 contacts the anode electrode 40, and the second p-type semiconductor layer 62 forms pn-junction with the drift layer 30. In the example of FIG. 1, the second p-type semiconductor layer 62 also contacts the anode electrode 40 at its side surface. Examples of the material of the first and second p-type semiconductor layers 61 and 62 may include Si, GaAs, GaN, SiC, Ge, ZnSe, CdS, InP, SiGe, AlN, BN, AlGaN, NiO, Cu₂O, Ir₂O₃, and Ag₂O; however, the material of the second p-type semiconductor layer 62 needs to have a valence band upper end level lower than the valence band upper end level of the first p-type semiconductor layer 61. For example, the material of the first p-type semiconductor layer 61 may be NiO having an impurity concentration of about 1×10¹⁹ cm⁻³, and the material of the second p-type semiconductor layer 62 may be BN having an impurity concentration of about 1×10¹⁶ cm⁻³.

There is formed, on the back surface 22 of the semiconductor substrate 20, a cathode electrode 50 which is brought into ohmic contact with the semiconductor substrate 20. The cathode electrode 50 may have a multilayer structure of different metal films, such as Ti/Au or Ti/Al.

When a forward voltage is applied to the junction barrier Schottky diode 1 according to the present embodiment, two current paths from the anode electrode 40 to the drift layer 30 are formed. The first current path (“P1” in FIG. 1B) is a path along which current flows from the anode electrode 40 to the drift layer 30 without passing through the p-type semiconductor layer 60. The second current path (“P2” in FIG. 1B) is a path along which current flows by way of the p-type semiconductor layer 60.

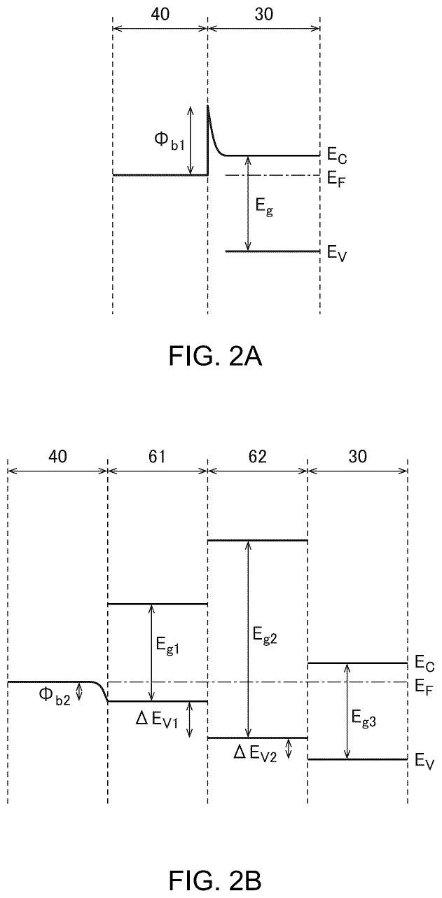

FIGS. 2A and 2B are energy band diagrams of the junction barrier Schottky diode 1 according to the present embodiment. FIG. 2A illustrates an energy band along the first current path P1, and FIG. 2B illustrates an energy band along the second current path P2.

As illustrated in FIG. 2A, the first current path P1, along which the anode electrode 40 and drift layer 30 are brought into Schottky contact with each other, functions as a Schottky barrier diode. Thus, the first current path P1 is thus turned ON first upon application of a forward voltage due to a low forward voltage and a high switching speed. The height of a Schottky barrier between the anode electrode 40 and drift layer 30 is Φ_{b1}. In FIGS. 2A and 2B, E_{F} denotes the Fermi level, E_{c} denotes a conduction band lower end level, E_{V} denotes a valence band upper end level, and E_{g} denotes an energy band gap.

On the other hand, as illustrated in FIG. 2B, the second current path P2 includes the p-type semiconductor layer 60 positioned between the anode electrode 40 and the drift layer 30. Thus, when a higher forward voltage is applied after current flows along the first current path P1, the second current path P2 is turned ON. This significantly reduces an ON-resistance.

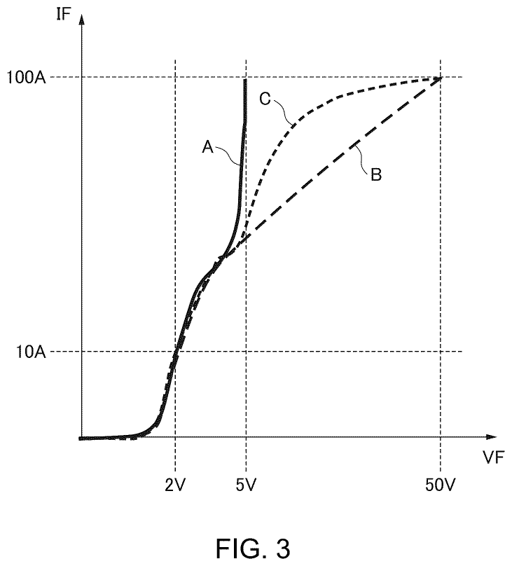

FIG. 3 is a graph illustrating the relation between a forward voltage VF and a forward current IF. In the graph, the sign A denotes characteristics of the junction barrier Schottky diode 1 according to the present embodiment, and the sign B denotes characteristics of a common Schottky barrier diode. As illustrated in FIG. 3, in a common Schottky barrier diode, a voltage of about 50 V is generated upon flowing of a sudden large current (surge current) of, e.g., 100 A, causing burning-out due to a large amount of heat generation. On the other hand, in the junction barrier Schottky diode 1 according to the present embodiment, even when a surge voltage of 100 A flows, a voltage to be generated can be reduced to about 5 V due to turning-ON of the second current path P2.

In addition, in the present embodiment, the first p-type semiconductor layer 61 and second p-type semiconductor layer 62 are arranged in this order between the anode electrode 40 and the drift layer 30.

As illustrated in FIG. 2B, a difference in energy between the Fermi level E_{F} and the valence band upper end level of the first p-type semiconductor layer 61 is Φ_{b2}, a difference in energy between the valence band upper end level of the first p-type semiconductor layer 61 and that of the second p-type semiconductor layer 62 is ΔE_{V1}, and a difference in energy between the valence band upper end level of the second p-type semiconductor layer 62 and that of the drift layer 30 is ΔE_{V2}. The first p-type semiconductor layer 61 has a band gap of E_{g1}, the second p-type semiconductor layer 62 has a band gap of E_{g2}, and the drift layer 30 has a band gap of E_{g3}. In the present embodiment, the valence band upper end level of the second p-type semiconductor layer 62 is lower than that of the first p-type semiconductor layer 61, so that the energy differences Φ_{b2} and ΔE_{V2} decrease as compared with when a single semiconductor material is used for the p-type semiconductor layer 60. This reduces energy required for hole injection into the drift layer 30 and reduces contact resistance between the anode electrode 40 and the p-type semiconductor layer 60, so that surge resistance increases as compared with when a single semiconductor material is used for the p-type semiconductor layer 60.

The materials of the first and second p-type semiconductor layers 61 and 62 may be materials for which the energy differences Φ_{b2} and ΔE_{V2} are equal to or less than 1 eV and 2 eV, respectively. For example, when NiO and BN are selected for the first p-type semiconductor layer 61 and the second p-type semiconductor layer 62, respectively, the band gap E_{g1} of NiO becomes about 3.7 eV, and the band gap E_{g2} of BN becomes about 6.2 eV, with the result that the energy difference Φ_{b2} becomes equal to or lea than 0.5 eV. This allows ohmic contact between the anode electrode 40 and the first p-type semiconductor layer 61. Further, in this case, the energy difference ΔE_{V2} also satisfies the above condition (2 eV or less), thus sufficiently reducing the energy required for hole injection into the drift layer 30. Alternatively, in order to make the energy differences Φ_{b2} and ΔE_{V2} equal to or less than 1 eV and 2 eV, respectively, NiO and AlN, Cu₂O and BN, Cu₂O and AlN, GaN and BN, AlGaN and BN, or CuGaO₂ and BN may be selected for the first p-type semiconductor layer 61 and the second p-type semiconductor layer 62, respectively. On the other hand, when ohmic contact between the anode electrode 40 and the p-type semiconductor layer 60 cannot be achieved due to the use of a single semiconductor material for the p-type semiconductor layer 60, a relatively large voltage may be generated by the surge current as indicated by the characteristic curve C in the graph of FIG. 3.

As described above, in the junction barrier Schottky diode 1 according to the present embodiment, the p-type semiconductor layer 60 is constituted by the first and second p-type semiconductor layers 61 and 62, so that surge resistance increases as compared with when a single semiconductor material is used for the p-type semiconductor layer 60. In addition, the p-type semiconductor layer 60 is formed on the flat upper surface 31 of the drift layer 30, thus making the manufacturing process simple.

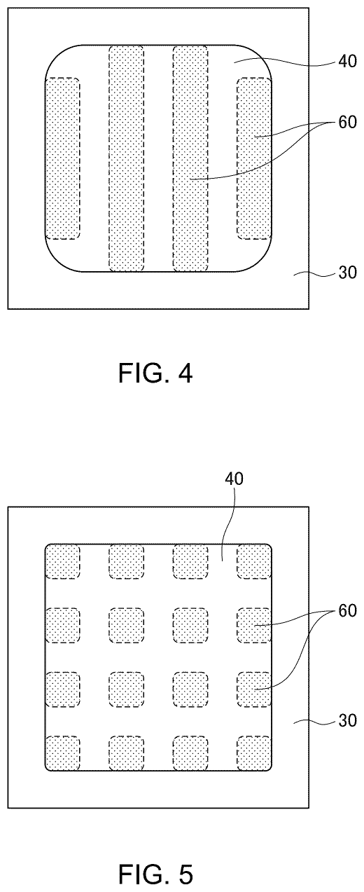

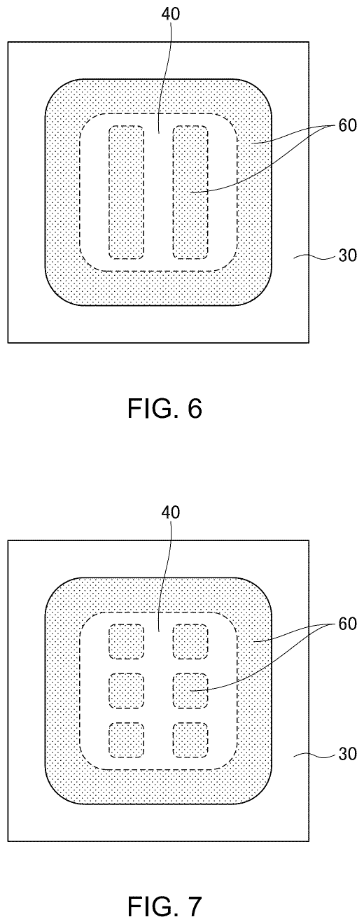

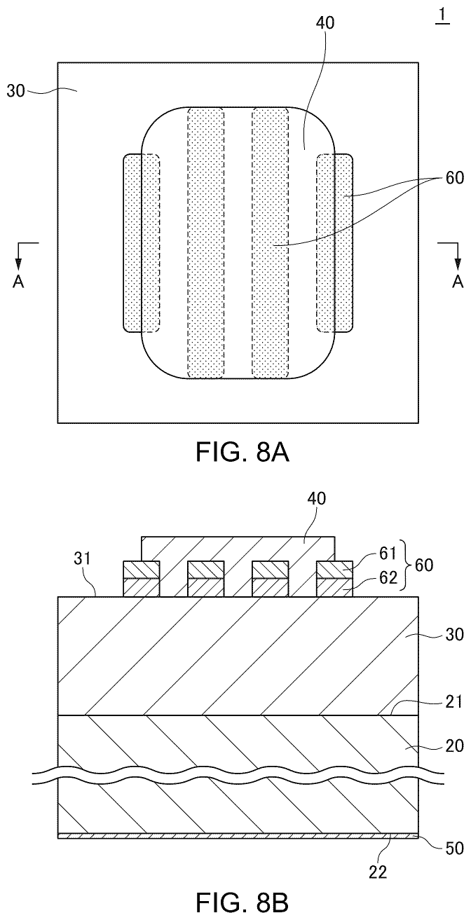

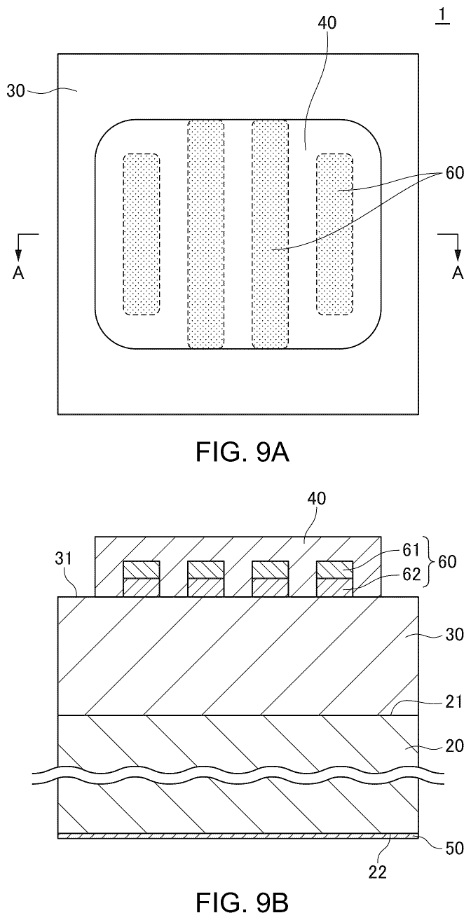

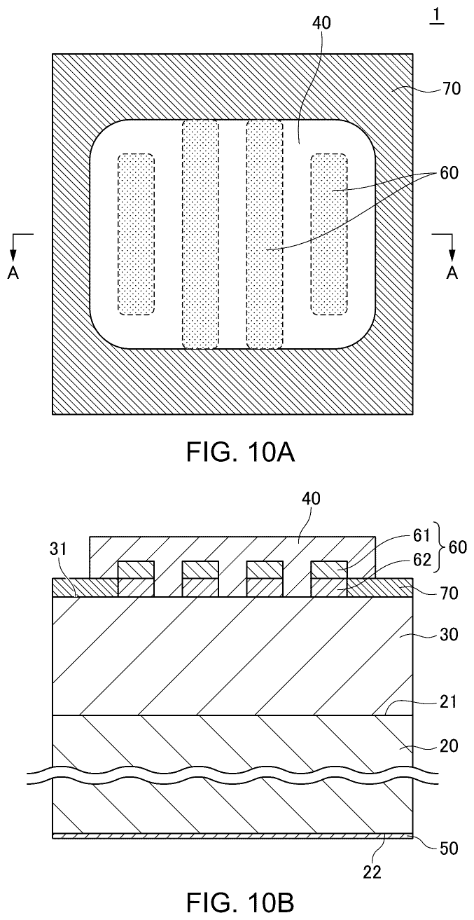

The shape of the p-type semiconductor layer 60 in a plan view is not limited to that illustrated in FIG. 1A. The p-type semiconductor layer 60 may have a stripe shape as in a first modification illustrated in FIG. 4, a dotted shape as in a second modification illustrated in FIG. 5, a shape formed by a combination of ring and stripe as in a third modification illustrated in FIG. 6, a shape formed by a combination of ring and dots as in a fourth modification illustrated in FIG. 7, a shape not covered in some part thereof with the anode electrode 40 as in a fifth modification illustrated in FIGS. 8A and 8B, or may be designed such that the arrangement range thereof is smaller than the width of the anode electrode 40 as in a sixth modification illustrated in FIGS. 9A and 9B. Further, the junction barrier Schottky diode 1 according to the present embodiment may be configured such that a field insulating film 70 is additionally provided on the upper surface 31 of the drift layer 30 and, on the field insulating film 70, the end portions of the anode electrode 40 are disposed as in a seventh modification illustrated in FIG. 10. Employing such a field plate structure can relax an electric field to be applied to the drift layer 30.

### Second Embodiment

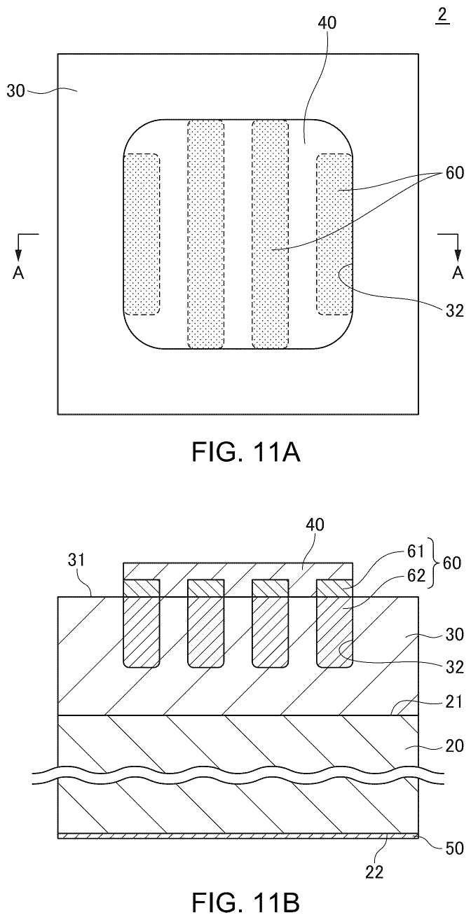

FIG. 11A is a schematic plan view illustrating the configuration of a junction barrier Schottky diode 2 according to a second embodiment of the present disclosure and FIG. 11B is a schematic cross-sectional view taken along the line A-A in FIG. 11A.

As illustrated in FIGS. 11A and 11B, the junction barrier Schottky diode 2 according to the second embodiment differs from the junction barrier Schottky diode 1 according to the first embodiment in that the second p-type semiconductor layer 62 is filled in a trench 32 formed in the drift layer 30. Other basic configurations are the same as those of the junction barrier Schottky diode 1 according to the first embodiment, so the same reference numerals are given to the same elements, and overlapping description will be omitted.

The trench 32 extends from the upper surface 31 of the drift layer 30 to a depth that does not reach the semiconductor substrate 20 and is filled with the second p-type semiconductor layer 62. For example, the depth of the trench 32 may be set to about 3 μm, and the width thereof may be set to about 1.5 μm. The first p-type semiconductor layer 61 is formed outside the trench 32 so as to contact the second p-type semiconductor layer 62. Thus, in the present embodiment, the node electrode 40 and the second p-type semiconductor layer 62 do not directly contact each other.

As described above, in the junction barrier Schottky diode 2 according to the second embodiment, the second p-type semiconductor layer 62 is filled in the trench 32 provided in the drift layer 30, thereby increasing contact area between the second p-type semiconductor layer 62 and the drift layer 30, which in turn can reduce the resistance value of the second current path P2.

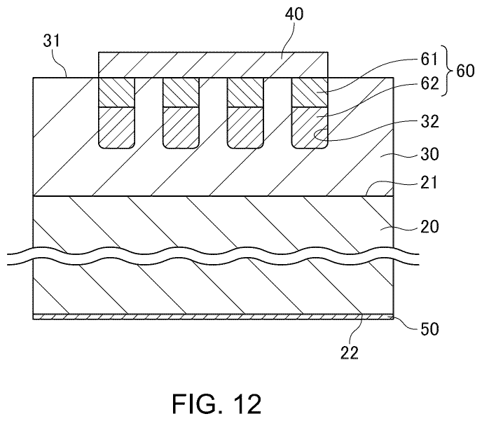

Further, although the second p-type semiconductor layer 62 is completely filled in the trench 32 in the example illustrated in FIGS. 11A and 11B, it may partially be provided outside the trench 32. Alternatively, as in a modification illustrated in FIG. 12, the entire p-type semiconductor layer 60 including the first p-type semiconductor layer 61 may be filled in the trench 32.

### Third Embodiment

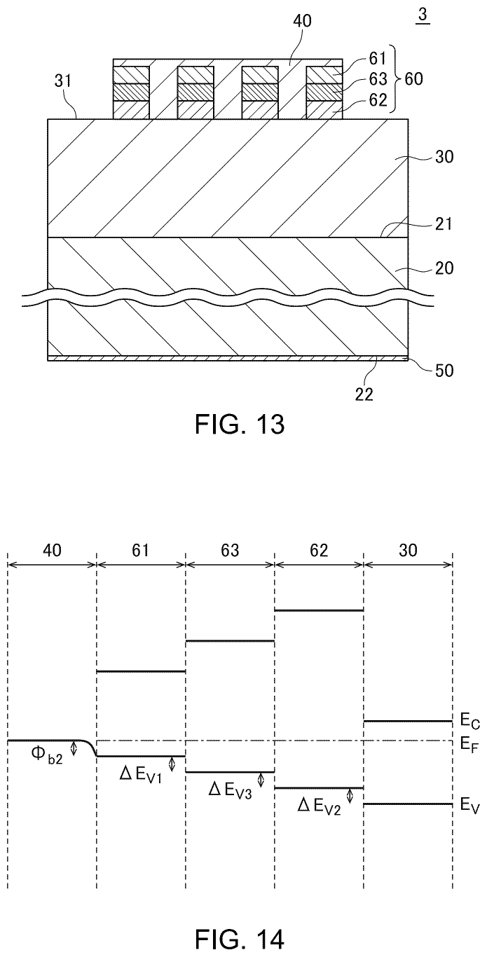

FIG. 13 is a schematic cross-sectional view illustrating the configuration of a junction barrier Schottky diode 3 according to a third embodiment of the present disclosure.

As illustrated in FIG. 13, the junction barrier Schottky diode 3 according to the third embodiment differs from the junction barrier Schottky diode 1 according to the first embodiment in that the p-type semiconductor layer 60 further includes a third p-type semiconductor layer 63. Other basic configurations are the same as those of the junction barrier Schottky diode 1 according to the first embodiment, so the same reference numerals are given to the same elements, and overlapping description will be omitted.

The third p-type semiconductor layer 63 is positioned between the first and second p-type semiconductor layers 61 and 62. As the material of the third p-type semiconductor layer 63, a material whose valence band upper end level is lower than that of the first p-type semiconductor layer 61 and higher than that of the second p-type semiconductor layer 62 is selected.

FIG. 14 is an energy band diagram of the junction barrier Schottky diode 3 according to the present embodiment, which illustrates an energy band along the second current path P2.

As illustrated in FIG. 14, in the present embodiment, the p-type semiconductor layer 60 has a three-layer structure, so that it is possible to further reduce the energy difference Φ_{b2} between the Fermi level E_{F} and the valence band upper end level of the first p-type semiconductor layer 61 and the energy difference ΔE_{V2} between the valence band upper end level of the second p-type semiconductor layer 62 and that of the drift layer 30. This further reduces the energy required for hole injection into the drift layer 30 and contact resistance between the anode electrode 40 and the p-type semiconductor layer 60, making it possible to further increase surge resistance.

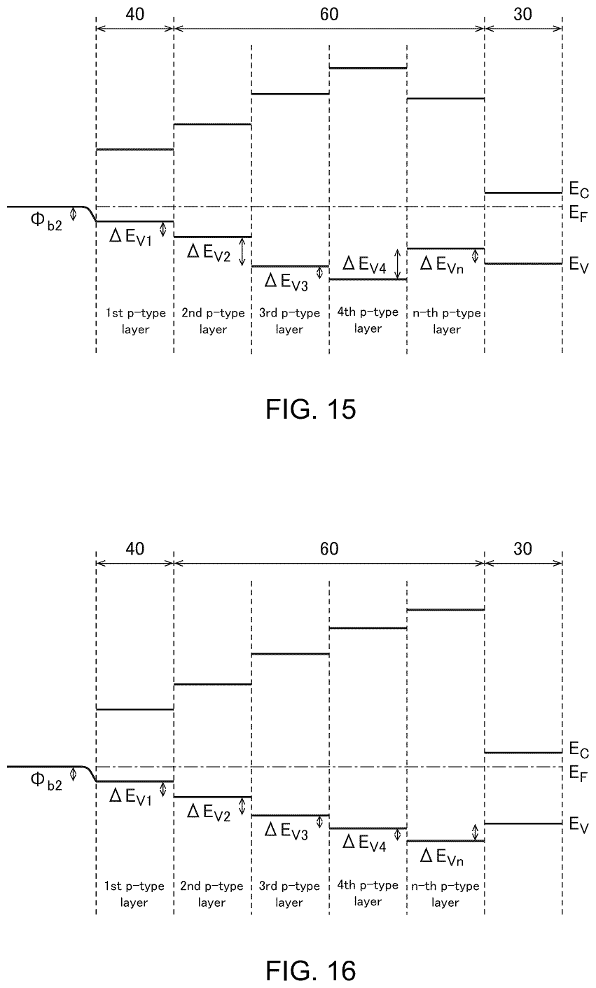

As exemplified by the junction barrier Schottky diode 3 according to the present embodiment, making the p-type semiconductor layer 60 have a three-layer structure can further reduce surge resistance. Further, it is possible to make the p-type semiconductor layer 60 have a four-layer or more structure. For example, assume that the p-type semiconductor layer has an n-layer structure. In this case, as illustrated in FIG. 15, there may partially exist a combination of two adjacent p-type semiconductor layers in which one (fourth p-type layer in FIG. 15) positioned on the anode electrode 40 side has a valence band upper end level lower than that of the other (n-th p-type layer in FIG. 15) positioned on the drift layer 30 side. Further, as illustrated in FIG. 16, the valence band upper end level of the p-type semiconductor layer (n-th p-type layer in FIG. 16 positioned closest to the drift layer 30 may be lower than the valence band upper end level of the drift layer 30.

While the embodiments of the present disclosure have been described, the present disclosure is not limited to the above embodiments, and various modifications may be made within the scope of the present disclosure, and all such modifications are included in the present disclosure.

The technology according to the present disclosure includes the following configuration examples but not limited thereto.

A junction barrier Schottky diode according to the present disclosure includes: a semiconductor substrate; a drift layer provided on the semiconductor substrate; an anode electrode contacting the drift layer; a cathode electrode contacting the semiconductor substrate; and a p-type semiconductor layer contacting both the anode electrode and the drift layer. The p-type semiconductor layer includes a first p-type semiconductor layer contacting the anode electrode and a second p-type semiconductor layer contacting the drift layer, and the second p-type semiconductor layer is lower in valence band upper end level than the first p-type semiconductor layer.

According to the present disclosure, using the two p-type semiconductor layers having different valence band upper end levels can reduce a difference between the Fermi level and the valence band upper end level of the p-type semiconductor layer and a difference between the valence band upper end level of the second p-type semiconductor layer and that of the drift layer.

In the present disclosure, the second p-type semiconductor layer and the first p-type semiconductor layer may be stacked in this order on a flat upper surface of the drift layer. This can make the manufacturing process simple.

In the present disclosure, the drift layer may have a trench, and at least a part of the p-type semiconductor layer may be embedded in the trench. This can increase contact area between the p-type semiconductor layer and the drift layer.

In the present disclosure, an energy difference between a Fermi level and the valence band upper end level of the first p-type semiconductor layer may be equal to or less than 1 eV, and an energy difference between the valence band upper end level of the second p-type semiconductor layer and a valence band upper end level of the drift layer may be equal to or less than 2 eV. This allows ohmic contact between the anode electrode and the first p-type semiconductor layer and can sufficiently reduce energy required for hole injection into the drift layer.

In the present disclosure, the p-type semiconductor layer may further include a third p-type semiconductor layer positioned between the first p-type semiconductor layer and the second p-type semiconductor layer, and the third p-type semiconductor layer may be lower in valence band upper end level than the first p-type semiconductor layer and higher in valence band upper end level than the second p-type semiconductor layer. This can further increase surge resistance.

As described above, according to the present disclosure, the surge resistance of a junction barrier Schottky diode can be increased.

What is claimed is:

1. A junction barrier Schottky diode comprising:
a semiconductor substrate;
a drift layer provided on the semiconductor substrate;
an anode electrode contacting the drift layer;
a cathode electrode contacting the semiconductor substrate; and
a p-type semiconductor layer contacting both the anode electrode and the drift layer,
wherein the p-type semiconductor layer includes a first p-type semiconductor layer contacting the anode electrode and a second p-type semiconductor layer contacting the drift layer, and
wherein the second p-type semiconductor layer is lower in valence band upper end level than the first p-type semiconductor layer.

2. The junction barrier Schottky diode as claimed in claim 1, wherein the second p-type semiconductor layer and the first p-type semiconductor layer are stacked in this order on a flat upper surface of the drift layer.

3. The junction barrier Schottky diode as claimed in claim 1,
wherein the drift layer has a trench, and
wherein at least a part of the p-type semiconductor layer is embedded in the trench.

4. The junction barrier Schottky diode as claimed in claim 1,
wherein an energy difference between a Fermi level and the valence band upper end level of the first p-type semiconductor layer is equal to or less than 1 eV, and
wherein an energy difference between the valence band upper end level of the second p-type semiconductor layer and a valence band upper end level of the drift layer is equal to or less than 2 eV.

5. The junction barrier Schottky diode as claimed in claim 1,
wherein the p-type semiconductor layer further includes a third p-type semiconductor layer positioned between the first p-type semiconductor layer and the second p-type semiconductor layer, and
wherein the third p-type semiconductor layer is lower in valence band upper end level than the first p-type semiconductor layer and higher in valence band upper end level than the second p-type semiconductor layer.
